(19) United States
(12) Patent Application Publication
(10) Pub. No.: US 2009/0134481 A1
(43) Pub. Date: May 28, 2009

(54) Molded Sensor Package and Assembly Method

(75) Inventor: Dipak Sengupta, Boxboro, MA (US)

Correspondence Address: BROMBERG & SUNSTEIN LLP, 125 SUMMER STREET, BOSTON, MA, 02110-1618, US

(73) Assignee: ANALOG DEVICES, INC., Norwood, MA (US)

(21) Appl. No.: 11/946,539

(22) Filed: Nov. 28, 2007

(51) Int. Cl. H01L 29/84; H01L 31/18; H01L 31/0203; H01L 21/56

(52) U.S. Cl. 257/415; 438/51; 257/433; 438/64; 257/E31.117; 257/E29.324; 257/E21.502

(57) ABSTRACT

A method of forming a molded sensor includes providing a sensor assembly having a sensor, and a cap coupled to a portion of the sensor, the cap having an opening and forming an interior area. The method also includes blocking the opening in the cap, and molding a moldable material around a portion of the sensor assembly and a portion of a base such that the moldable material is coupled to the sensor assembly and the base, the interior area being substantially free of the moldable material.

### FIELD OF THE INVENTION

The invention generally relates to packages and, more particularly, the invention relates to molded MEMS sensor and/or molded image sensor packages.

### BACKGROUND OF THE INVENTION

A variety of different applications use sensor systems to detect the movement of an underlying object or the presence of a substance or condition in a particular environment, such as sensors that detect light, pressure, humidity, sound and gases. For example, pressure sensors may be used in automotive, medical, aerospace and marine applications. Sensors employing microelectromechanical systems (MEMS) devices are increasingly used in such applications due to their relatively small size and their capability to detect relatively small amounts or changes in the measured item. Similarly, sensors employing image sensors (e.g., a charge-coupled device (CCD) or a Complementary Metal Oxide Semiconductor (CMOS) image sensor used in digital imaging) are increasingly used due to their relatively small size and their capability to detect relatively small amounts or changes in the light measured.

MEMS devices typically employ a movable mass or flexible membrane formed with one or more fixed, non-moving structures. For example, the movable mass may be suspended in a plane above a substrate or the flexible membrane may be formed above the substrate and movable with respect to the substrate. Because of the mechanical moving structures involved and the typical required device sensitivities, MEMS devices are commonly covered with a cap structure to protect the MEMS structures from hazards that may impact the functioning of the device, e.g., from gases, particles, moisture, etc. For some sensors, however, e.g., chemical, pressure, humidity and/or temperature sensors, a portion of the sensor needs to maintain an exposure to the surrounding or ambient atmosphere in order to function properly. In image sensors, however, a glass lid typically covers the imaging device structure (e.g., the CCD or CMOS device) so that a portion of the sensor allows light to access the sensor die surface in order to function properly.

MEMS or imaging devices are typically mounted or secured within packages. These packages may protect the device and permit electrical connections from the device to other components or systems. One type of package currently used for some MEMS devices that maintain an exposure to the surrounding atmosphere is a premolded leadframe package. These types of packages typically include a preformed or premolded housing having walls surrounding a leadframe at the base of the walls to form a cavity. The electrical connections are then usually provided through the walls of the housing and the device is coupled to the leadframe at the bottom of the cavity. As a result, premolded leadframe packages typically require a labor intensive, custom assembly to mount the individual devices within the premolded package cavity and, thus, are relatively costly to manufacture.

### SUMMARY OF THE INVENTION

In accordance with one embodiment of the invention, a method of forming a molded sensor includes providing a sensor assembly having a sensor, and a cap coupled to a portion of the sensor, the cap having an opening and forming an interior area. The method further includes blocking the opening in the cap, and molding a moldable material around a portion of the sensor assembly and a portion of the base such that the moldable material is coupled to the sensor assembly and the base, the interior area being substantially free of the moldable material.

In accordance with related embodiments, the method may further include providing an integrated circuit die, such that the integrated circuit die is between the sensor assembly and the base, and electrically coupling the integrated circuit die to the base, wherein the moldable material is further molded around a portion of the integrated circuit die such that the moldable material is coupled to the integrated circuit die. The sensor may be a MEMS sensor or an image sensor. The opening in the cap may be formed before or after coupling the cap to the portion of the sensor. The sensor assembly may include a plurality of sensors and a plurality of caps, one cap coupled to a portion of each sensor, the plurality of sensors and the plurality of caps forming an array. The method may further include separating the array into a plurality of molded sensors such that each molded sensor includes at least one sensor, at least one cap and a base molded in the moldable material. The base may include a leadframe or a laminated, layered material having vias. The method may further include unblocking the opening in the cap after molding the moldable material.

In accordance with another embodiment of the invention, a method of forming a molded sensor includes providing a sensor assembly having a sensor, and a cap coupled to a portion of the sensor, the cap forming an interior area. The method may further include molding a moldable material around a portion of the sensor assembly and a portion of the base such that the moldable material is coupled to the sensor assembly and the base, the interior area being substantially free of the moldable material, and forming an opening in the cap.

In accordance with related embodiments, the method may further include providing an integrated circuit die, such that the integrated circuit die is between the sensor assembly and the base, and electrically coupling the integrated circuit die to the base, wherein the moldable material is further molded around a portion of the integrated circuit die such that the moldable material is coupled to the integrated circuit die. The sensor may be a MEMS sensor or an image sensor. The sensor assembly may include a plurality of sensors and a plurality of caps, one cap coupled to a portion of each sensor, the plurality of sensors and the plurality of caps forming an array. The method may further include separating the array into a plurality of molded sensors such that each molded sensor includes at least one sensor, at least one cap and a base molded in the moldable material. The base may include a leadframe or a laminated, layered material having vias. The opening may be formed with a laser ablation process.

In accordance with another embodiment of the invention, a molded sensor includes a sensor, a cap coupled to a portion of the sensor, the cap having an opening and forming an interior area, and a molding material coupled to the sensor, the cap and the base such that the molding material encapsulates a portion of the sensor, a portion of the cap and a portion of the base, the interior area being substantially free of the molding material.

In accordance with related embodiments, the molded sensor may further include an integrated circuit die coupled to the sensor and electrically coupled to the base such that the integrated circuit die may be between the sensor and the base, wherein the molding material is further coupled to the integrated circuit die and further encapsulates a portion of the integrated circuit die. The sensor may be a MEMS sensor or an image sensor. The base may include a leadframe or a laminated, layered material having vias.

### BRIEF DESCRIPTION OF THE DRAWINGS

The foregoing advantages of the invention will be appreciated more fully from the following further description thereof with reference to the accompanying drawings wherein:

FIG. 1 schematically shows a molded sensor system according to illustrative embodiments of the present invention;

FIG. 2 schematically shows a cross sectional view of a molded MEMS sensor without the molding material according to illustrative embodiments of the present invention;

FIG. 3 schematically shows a cross sectional view of a molded MEMS sensor according to illustrative embodiments of the present invention;

FIG. 4 shows a process of forming a molded MEMS sensor according to illustrative embodiments of the present invention;

FIG. 5 schematically shows a cross sectional view of a molded image sensor according to illustrative embodiments of the present invention;

FIG. 6 shows a process of forming a molded image sensor according to illustrative embodiments of the present invention;

FIG. 7 schematically shows a top view of an array of molded sensors according to illustrative embodiments of the present invention; and

FIG. 8 shows a cross sectional view along line A-A of FIG. 7, according to illustrative embodiments of the present invention.

### DESCRIPTION OF ILLUSTRATIVE EMBODIMENTS

Embodiments of the present invention include a molded MEMS sensor and/or a molded image sensor package and assembly method using a molding material that molds the structures together. The molding process allows for the manufacture of multiple sensor arrays which may then be formed into individual molded sensors (e.g., using device singulation such as wafer sawing), providing a low cost, high throughput packaging method. Embodiments include molding the MEMS sensor or image sensor onto a base, such as a leadframe or a laminated, layered material having vias such as, for example, FR4, BT resin, flexible polyimide or ceramic materials. Details of illustrative embodiments are discussed below.

Although the following discussion describes various relevant steps of forming a molded MEMS sensor or molded image sensor, it does not describe all the required steps. Other processing steps may also be performed before, during, and/or after the discussed steps. Such steps, if performed, have been omitted for simplicity. The order of the processing steps may also be varied and/or combined. Accordingly, some steps may not be described and shown.

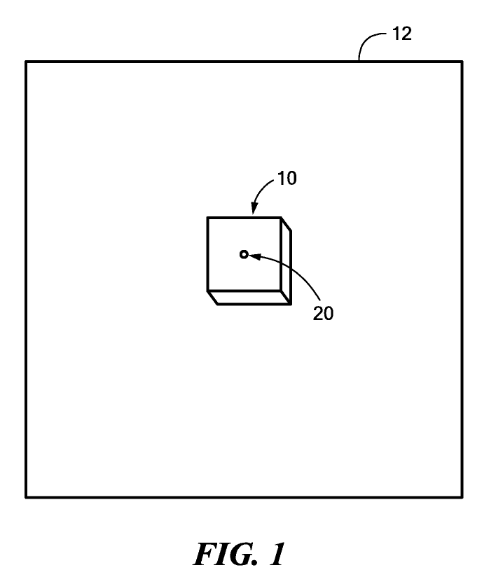

FIG. 1 schematically shows a molded sensor system according to illustrative embodiments of the present invention. The molded sensor system includes a molded sensor 10 (e.g., molded MEMS sensor or molded image sensor) coupled to a base 12. The base 12 may be any board, chip, material, etc. (e.g., a printed circuit board, a carrier chip, a leadframe, a laminated layered material with vias such as, for example, FR4, BT resin, flexible polyimide or ceramic materials) that connects the molded sensor 10 to other components and/or systems. For example, the molded sensor system and/or one or more molded sensors 10 thereon may communicate with a central computer (not shown) through some interconnection medium. Although a single molded sensor 10 is shown in FIG. 1, the molded sensor system may include a plurality of molded sensors 10 coupled to the base 12.

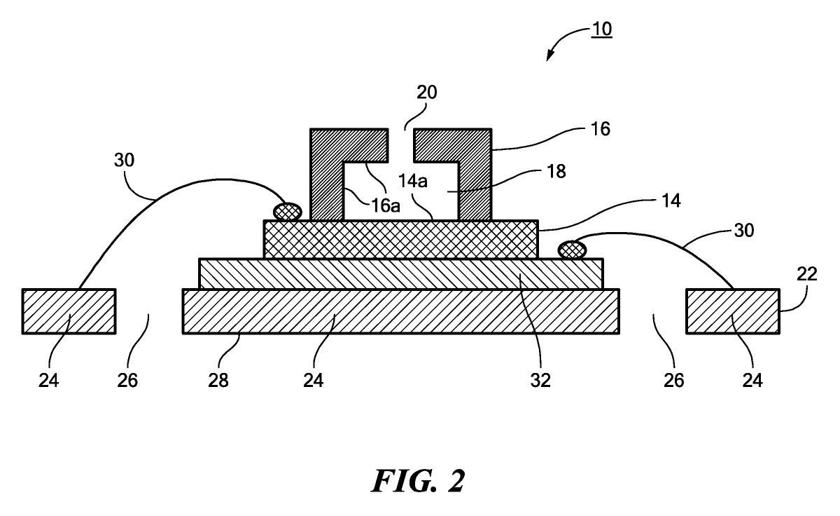

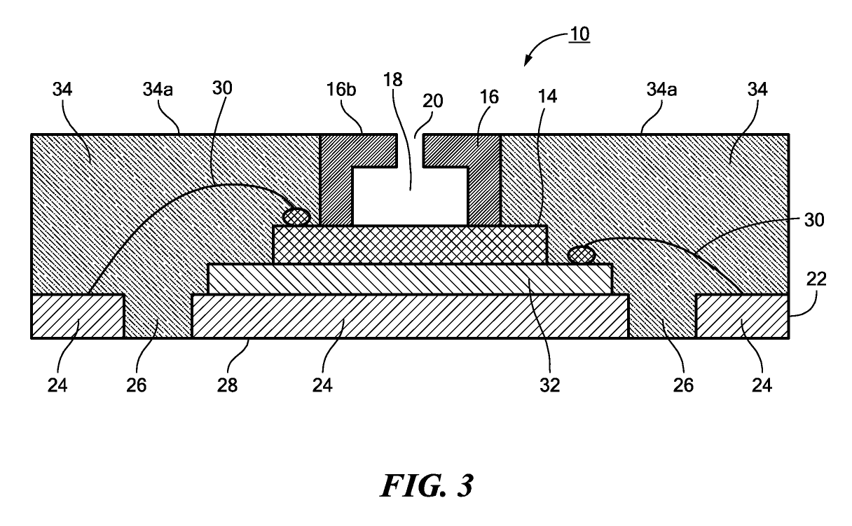

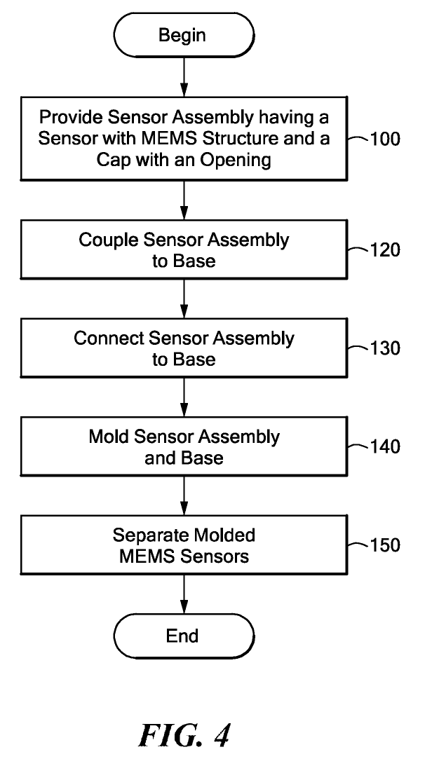

FIGS. 2 and 3 schematically show a cross sectional view of a molded MEMS sensor 10 without the molding material and with the molding material, respectively. FIG. 4 shows a process of forming a molded MEMS sensor according to illustrative embodiments of the present invention. Referring to FIGS. 2-4, the process of forming the molded MEMS sensor 10 begins at step 100, which provides a sensor assembly. The sensor assembly includes a MEMS sensor 14 having MEMS structure (not shown) and a cap 16 coupled to a portion of the MEMS sensor 14. The cap 16 may be positioned on the MEMS sensor 14 such that the portion of the cap 16 that contacts the MEMS sensor 14 surrounds or circumscribes one or more MEMS structures formed on the MEMS sensor 14. The cap 16 may also be positioned to surround circuitry formed on the MEMS sensor 14 and coupled to the MEMS structure. The cap 16 forms an interior area 18 between the inside surface 16a of the cap 16 and the surface 14a of the MEMS sensor 14 having the MEMS structure. As such, the area 18 formed is adjacent to or surrounds the MEMS structure formed on the MEMS sensor 14.

The cap 16 may include a hole or opening 20 through which the ambient or surrounding atmosphere may enter into the interior area 18. This allows the MEMS structure to be exposed to the atmosphere surrounding the MEMS sensor 14. Thus, the MEMS sensor 14 may be any sensor that requires the sensor to be exposed to the surrounding atmosphere, e.g., chemical, pressure, humidity, temperature sensors. Similarly, the MEMS structure may be a flexible membrane formed above a substrate and movable with respect to the substrate or a movable mass suspended in a plane above a substrate as is well known to those skilled in the art.

The cap 16 may be coupled to a portion of the MEMS sensor 14 using bonding techniques well known to those skilled in the art, e.g., metal bonding, adhesive bonding, glass frit bonding. The cap 16 may be formed from silicon, glass or other materials. The opening 18 may be formed in the cap 16 before or after attachment to the MEMS sensor 14. For example, the opening 18 may be formed in the cap 16 before attachment using standard patterning or fabrication processes well known to those skilled in the art, e.g., photolithography and etching techniques, such as reactive ion etching or laser drilling, to remove a selected portion of the cap 16. Alternatively, for example, the opening 18 may be formed in the cap 16 after attachment using a laser ablation process to remove a selected portion of the cap 16 as is well known to those skilled in the art. When the opening 18 is formed after attachment, the opening 18 may be formed before a molding process or after the molding process as discussed in more detail below.

In step 120, the sensor assembly 14, 16 may be coupled to a base 22 using bonding techniques (e.g., conductive or non conductive epoxies, metal solder, etc.) well known to those skilled in the art. The base 22 may be any material or layer(s) that allows for an electrical connection of the assembled layers thereon (e.g., sensor assembly 14, 16) to another component and/or system, such as the base 12 shown in FIG. 1. For example, the base 22 may be a leadframe or a laminated, layered material having vias, such as a layered material that includes FR4, BT resin, flexible polyimide or ceramic materials, as is well known to those skilled in the art. As shown in FIGS. 2 and 3, for example, a leadframe base 22 may include various metal areas 24 and open areas 26 that do not include metal. In addition, the base 22 may include a backing material 28 that the metal areas 24 and the open areas 26 contact, which is on the opposite surface of the base 22 than where the sensor assembly 14, 16 is coupled. The backing material 28 may be a temporary layer that is subsequently removed after further processing of the molded MEMS sensor 10 as described in more detail below.

One or more layers may also be coupled to the base 22 using bonding techniques well known to those skilled in the art. For example, a chip or die 32 that includes an integrated circuit (IC), such as an application specific integrated circuit (ASIC), may be coupled to the base 22 and then the sensor assembly 14, 16 may be attached to the IC die 32. Although the IC die 32 is shown between the base 22 and the sensor assembly 14, 16, the IC die 32 may be next to the sensor assembly 14, 16 (e.g., side-by-side multichip module configuration) and/or between the base 22 and the sensor assembly 14, 16 (e.g., stacked die configuration).

In step 130, the sensor assembly (e.g., the MEMS sensor 14 and/or the cap 16) may be electrically connected to the base 22 using an electrical connection 30, such as leads and wire bonds or solder bumps. The electrical connection 30 connects the MEMS sensor 14 and/or the cap 16 to an electrically conductive area on the base 22, such as the metal area 24 on a leadframe. Other layers that may be stacked on the base 22, (e.g., in a side-by-side configuration or a stacked die configuration), may also be electrically connected to the base 22. For example, as shown in FIGS. 2 and 3, the electrical connection 30 connects the IC die 32 to an electrically conductive area on the base 22, such as another metal area 24 on the leadframe. Although the connection 30 is shown as leads, this is for illustration purposes only and other types of connections are possible to electrically connect the sensor(s) 14 and IC(s) 32 to the metal area 24 in the leadframe so as to electrically connect them to the base 12 as is well known to those skilled in the art.

In step 140, once the desired electrical connection(s) are made from the attached layers (e.g., the MEMS sensor 14, the cap 16, the IC die 32) to the base 22, a moldable material 34 may contact a portion of the assembled layers and the electrical connection(s) 30 and mold them together in a molding step. FIGS. 2 and 3 show the molded MEMS sensor 10 before and after the molding step, respectively. As shown in FIG. 3, this process encapsulates each assembled layer and the electrical connection(s) 30. The moldable material 34 may enter or flow into open areas 26 of the base 22. If a backing material 28 is used on the lead surface, then the backing material 28 may substantially prevent the moldable material 34 from going beyond the open areas 26 and contacting the other surface of the base 22, e.g., the surface opposite from where the layers (e.g., the MEMS sensor 14, the cap 16, the IC die 32) are coupled.

A plug or plunger (not shown) may be temporarily provided at the opening 20 of the cap 16 (if one has already been formed) before and during the molding process in order to block the opening 20 and substantially prevent the moldable material 34 from entering into the interior area 18 and contacting the MEMS structure. The plunger process may use commercially available processes and fixturing to isolate a selective die surface from a mold ingress as well known to those skilled in the art. The plunger may also cover a portion of the cap 16, e.g., surface 16b, so that the moldable material 34 does not substantially flow over or contact the cap surface 16b. As a result, the cap surface 16b is substantially planar with the surface 34a of the moldable material 34. After the moldable material 34 has molded the components together in the molding process, the plunger is removed from the opening 20 (if one has already been formed) and any portion of the cap 16, unblocking the opening 20 in the cap 16 and uncovering the cap surface 16b. If the opening 20 has not previously been formed, the opening 20 may be formed after the plunger is removed from the cap surface 16b. This process allows the interior area 18 to be substantially free of the moldable material 34. The moldable material 34 may be any non-conductive material used for molding components together, such as a thermoset or thermoplastic polymer material, as is well known to those skilled in the art. Similarly, any molding process may be used to mold the moldable material 34 around the sensor assembly 14, 16, the IC die 32 and the base 22, such as a transfer molding or an injection molding process.

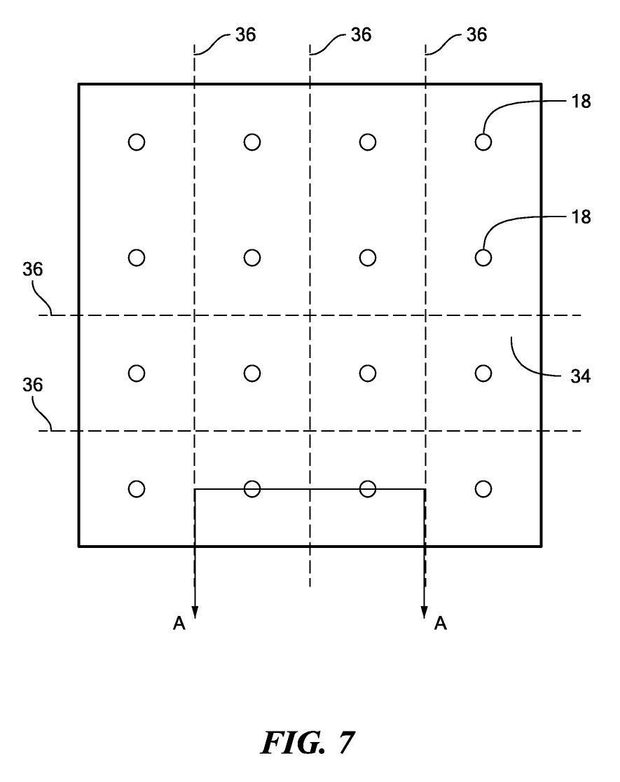

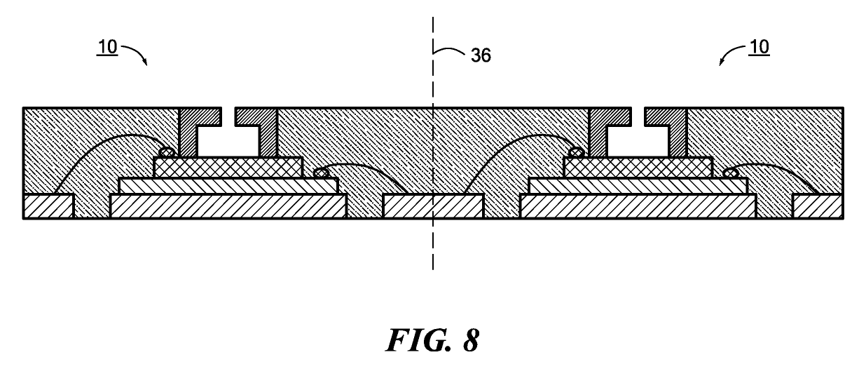

If an array of molded sensors 10 are formed, the array may be separated or diced into one or more individual molded sensors 10 (step 150) as described in more detail with respect to FIGS. 7 and 8 below.

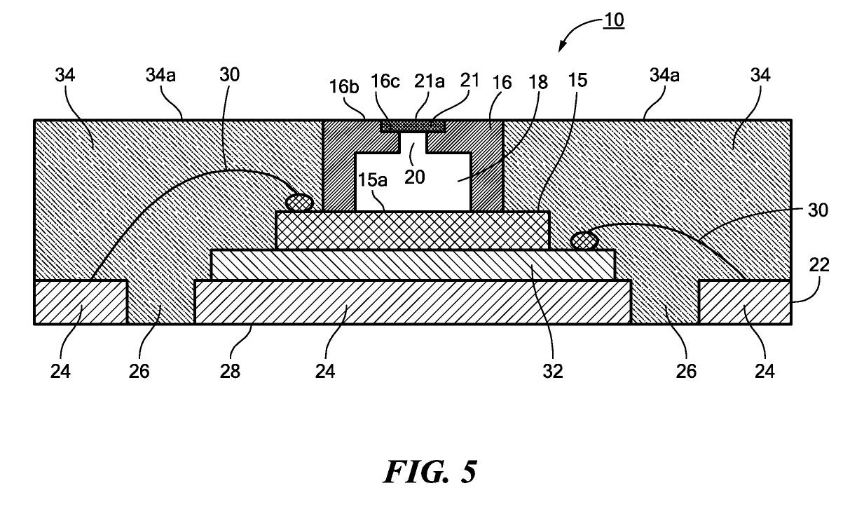

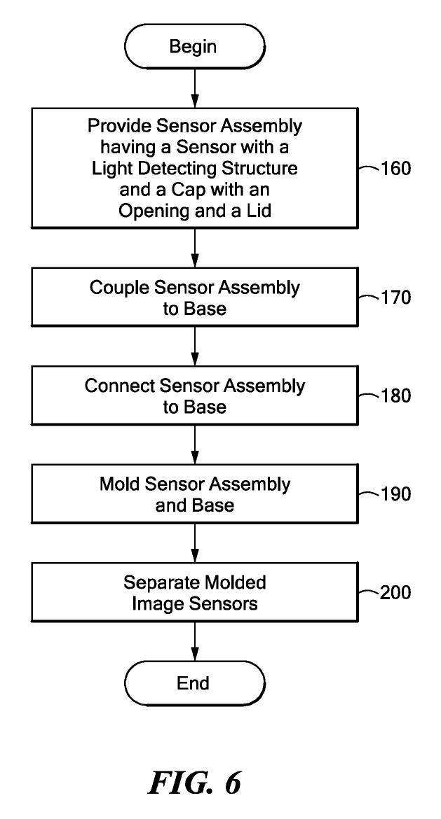

FIG. 5 schematically shows a cross sectional view of a molded image sensor 10 and FIG. 6 shows a process of forming a molded image sensor according to illustrative embodiments of the present invention. The process of forming the molded image sensor is similar to that described above and shown in FIGS. 2-4 except that the sensor assembly includes an image sensor 15 rather than a MEMS sensor 14. Thus, the process of forming the molded image sensor 10 begins at step 160, which provides a sensor assembly. The sensor assembly includes an image sensor 15 having light detecting structure (not shown) and a cap 16 coupled to a portion of the image sensor 15. Similar to that described above, the cap 16 may be positioned on the image sensor 15 such that the portion of the cap 16 that contacts the image sensor 15 surrounds or circumscribes one or more light detecting structures formed on the image sensor 15. The cap 16 may also be positioned to surround circuitry formed on the image sensor 15 and coupled to the light detecting structure. The cap 16 forms an interior area 18 between the inside surface 16a of the cap 16 and the surface 15a of the image sensor 15 having the light detecting structure. As such, the area 18 formed is adjacent to or surrounds the light detecting structure formed on the image sensor 15.

The cap 16 includes a hole or opening 20 and a lid 21 located in the opening 20 through which light may enter into the interior area 18. This allows the image sensor 15 to be exposed to the light impinging on the sensor assembly. Thus, the image sensor 15 may be any sensor that requires the sensor to be exposed to light, e.g., CCD and/or CMOS image sensors. Similarly, the light detecting structure may be those structures formed on the image sensor 15 as is well known to those skilled in the art. The lid 21 may be formed from any light transmissive material (e.g., a glass lid with or without filters) and coupled to the cap 16 using bonding techniques well known to those skilled in the art, e.g., using epoxy. Similar to that mentioned above with respect to the MEMS sensor 14, the opening 18 may be formed in the cap 16 before or after attachment to the image sensor 15 using standard processes well known to those skilled in the art. When the opening 18 is formed after attachment, the opening 18 may be formed before or after the molding process as discussed above. The lid 21 may located be in the opening 18 or a portion of the opening 18. Alternatively, a notch 16c may be formed in the cap 16 using standard processes well known to those skilled in the art (e.g., using etching processes) and formed adjacent to the opening 18. The lid 21 may then be located in the notch 16c or in the notch 16c and in the opening 18 or a portion of the opening 18 so that the surface 21a of the lid 21 is substantially planar with the surface 16b of the cap 16.

In step 170, the sensor assembly 15, 16 may be coupled to a base 22 using bonding techniques well known to those skilled in the art. In step 180, the sensor assembly (e.g., the image sensor 15 and/or the cap 16) may be electrically connected to the base 22 using an electrical connection 30, such as leads and wire bonds or solder bumps. The electrical connection 30 connects the image sensor 15 and/or the cap 16 to an electrically conductive area on the base 22, such as the metal area 24 on a leadframe. Other layers may used as described above with reference to FIGS. 2-4. In step 190, once the desired electrical connection(s) are made from the attached layers (e.g., the image sensor 15, the cap 16, the IC die 32) to the base 22, a moldable material 34 may contact a portion of the assembled layers and the electrical connection(s) 30 and mold them together in a molding step. If an array of molded sensors 10 are formed, the array may be separated or diced into one or more individual molded sensors 10 (step 200) as described in more detail with respect to FIGS. 7 and 8 below.

Although a single molded sensor 10 having one or more MEMS structures as shown in FIGS. 2 and 3 or having one or more light detecting structures as shown in FIG. 5 may be formed, embodiments may also include multiple sensors 14 and/or 15 and caps 16 molded together to form an array of molded sensors 10, such as shown in FIG. 7. If an array of molded sensors 10 are formed, the array may be separated or diced into one or more individual molded sensors 10. For example, referring to FIGS. 7 and 8, the array may be separated along separation lines 36 using any device singulation process, such as wafer sawing, as is well known to those skilled in the art. The individual molded sensors 10 may each include at least one MEMS sensor 14 with one or more MEMS structures formed thereon and/or may each include at least one image sensor 15 with one or more light detecting structures formed thereon, at least one cap 16 coupled to the sensor 14 and/or 15 and the base 22 molded in the moldable material. The individual molded sensors 10 may also include other layers, such as the IC die 32, molded in the moldable material.

As mentioned above, other processing steps may be used to complete the process of forming the molded sensor 10. For example, embodiments may implement methods for integrating the molded sensor 10 with circuitry on another die. In addition, other processes may be used to integrate the molded sensor 10 in the molded sensor system, within packages, and/or with other components and/or devices such as a side-by-side Multichip module configuration or a System in Package configuration.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a molded sensor, the method comprising:
providing a sensor assembly having a sensor, and a cap coupled to a portion of the sensor, the cap having an opening and forming an interior area;
blocking the opening in the cap; and
molding a moldable material around a portion of the sensor assembly and a portion of a base such that the moldable material is coupled to the sensor assembly and the base, the interior area being substantially free of the moldable material.

2. The method of claim 1, further comprising:
providing an integrated circuit die, such that the integrated circuit die is between the sensor assembly and the base; and
electrically coupling the integrated circuit die to the base, wherein the moldable material is further molded around a portion of the integrated circuit die such that the moldable material is coupled to the integrated circuit die.

3. The method of claim 1, wherein the sensor is a MEMS sensor or an image sensor.

4. The method of claim 1, wherein the opening in the cap is formed after coupling the cap to the portion of the sensor.

5. The method of claim 1, wherein the opening in the cap is formed before coupling the cap to the portion of the sensor.

6. The method of claim 1, wherein the sensor assembly includes a plurality of sensors and a plurality of caps, one cap coupled to a portion of each sensor, the plurality of sensors and the plurality of caps forming an array.

7. The method of claim 6, further comprising:
separating the array into a plurality of molded sensors such that each molded sensor includes at least one sensor, at least one cap and a base molded in the moldable material.

8. The method of claim 1, wherein the base includes a leadframe or a laminated, layered material having vias.

9. The method of claim 1, further comprising:
unblocking the opening in the cap after molding the moldable material.

10. A method of forming a molded sensor, the method comprising:
providing a sensor assembly having a sensor, and a cap coupled to a portion of the sensor, the cap forming an interior area;
molding a moldable material around a portion of the sensor assembly and a portion of a base such that the moldable material is coupled to the sensor assembly and the base, the interior area being substantially free of the moldable material; and
forming an opening in the cap.

11. The method of claim 10, further comprising:
providing an integrated circuit die, such that the integrated circuit die is between the sensor assembly and the base; and
electrically coupling the integrated circuit die to the base, wherein the moldable material is further molded around a portion of the integrated circuit die such that the moldable material is coupled to the integrated circuit die.

12. The method of claim 10, wherein the sensor is MEMS sensor or an image sensor.

13. The method of claim 10, wherein the sensor assembly includes a plurality of sensors and a plurality of caps, one cap coupled to a portion of each sensor, the plurality of sensors and the plurality of caps forming an array.

14. The method of claim 13, further comprising:
separating the array into a plurality of molded sensors such that each molded sensor includes at least one sensor, at least one cap and a base molded in the moldable material.

15. The method of claim 10, wherein the base includes a leadframe or a laminated, layered material having vias.

16. The method of claim 10, wherein the opening is formed with a laser ablation process.

17. A molded sensor comprising:
a sensor electrically coupled to a base;
a cap coupled to a portion of the sensor, the cap having an opening and forming an interior area; and
a molding material coupled to the sensor, the cap and the base such that the molding material encapsulates a portion of the sensor, a portion of the cap and a portion of the base, the interior area being substantially free of the molding material.

18. The molded sensor of claim 17, further comprising:
an integrated circuit die coupled to the sensor and electrically coupled to the base such that the integrated circuit die is between the sensor and the base, wherein the molding material is further coupled to the integrated circuit die and further encapsulates a portion of the integrated circuit die.

19. The molded sensor of claim 17, wherein the sensor is a MEMS sensor or an image sensor.

20. The molded sensor of claim 17, wherein the base includes a leadframe or a laminated, layered material having vias.
